(19) United States
(12) Patent Application Publication
(10) Pub. No.: US 2007/0152325 A1
(43) Pub. Date: Jul. 5, 2007

(54) Chip package dielectric sheet for body-biasing

(75) Inventors: Ashay A. Dani, Chandler, AZ (US); Anna M. Prakash, Mesa, AZ (US); Saikumar Jayaraman, Chandler, AZ (US); Mitesh Patel, Phoenix, AZ (US); Vijay S. Wakharkar, Paradise Valley, AZ (US)

Correspondence Address: SCHWEGMAN, LUNDBERG, WOESSNER & KLUTH, P.A., P.O. BOX 2938, MINNEAPOLIS, MN, 55402, US

(73) Assignee: Intel Corporation

(21) Appl. No.: 11/323,243

(22) Filed: Dec. 30, 2005

(51) Int. Cl. H01L 23/34; H01L 21/48

(52) U.S. Cl. 257/717; 257/718; 257/720; 438/117; 257/E23.101

(57) ABSTRACT

A chip package includes a thermal interface material disposed between a die backside and a heat sink. A dielectric sheet is also disposed between the die backside and the heat sink. The dielectric sheet diminishes overall heat transfer from the die to the heat sink by a small fraction of total possible heat transfer without the dielectric sheet. A method of operating the chip includes biasing the chip with the dielectric sheet in place.

### TECHNICAL FIELD

Embodiments relate generally to a chip package fabrication. More particularly, embodiments relate to heat-transfer and current-leakage issues in chip packages.

### TECHNICAL BACKGROUND

Issues that affect packaged integrated circuit (IC) devices include heat management, current leakage, and clock speed, among others. An IC die that cannot adequately reject heat will be adversely affected in clock speed. An IC die that has significant current leakage through the backside will also be adversely affected in clock speed.

As die size and package size continue to be miniaturized, current leakage may exceed the current demand to operate the IC die. The mobile IC die segment of packaged IC devices is a particularly vulnerable area of technology as it is desired to improve battery life by decreasing electrical current demand.

### BRIEF DESCRIPTION OF THE DRAWINGS

In order to depict the manner in which the embodiments are obtained, a more particular description of embodiments briefly described above will be rendered by reference to exemplary embodiments that are illustrated in the appended drawings. Understanding that these drawings depict typical embodiments that are not necessarily drawn to scale and are not therefore to be considered to be limiting of its scope, the embodiments will be described and explained with additional specificity and detail through the use of the accompanying drawings in which:

FIG. 1 is a cross-section elevation of an apparatus that includes a dielectric sheet according to an embodiment;

FIG. 2 is a cross-section elevation of an apparatus that includes a dielectric sheet according to an embodiment;

FIG. 3 is a cross-section elevation of an apparatus that includes a dielectric sheet in an integrated heat spreader package according to an embodiment;

FIG. 4 is a cross-section elevation of an apparatus that includes a dielectric sheet in an integrated heat spreader and heat slug package according to an embodiment;

FIG. 5 is a cross-section elevation of an apparatus during the reworking of a flexible dielectric sheet according to an embodiment;

FIG. 6 is a cross-section elevation of an apparatus during the reworking of a rigid dielectric sheet according to an embodiment;

FIG. 7 is a flow chart that describes process flow embodiments; and

FIG. 8 is a cut-away elevation that depicts a computing system according to an embodiment.

### DETAILED DESCRIPTION

Embodiments in this disclosure relate to an apparatus that includes a dielectric sheet for heat transfer between the IC die and the heat spreader. Embodiments relate to both inorganic and organic dielectric sheets, as well as reworkable flexible and rigid dielectric sheets. Embodiments also relate to processes of assembling dielectric sheets into chip packages. Embodiments also relate to systems that incorporate dielectric sheets.

The following description includes terms, such as upper, lower, first, second, etc. that are used for descriptive purposes only and are not to be construed as limiting. The embodiments of an apparatus or article described herein can be manufactured, used, or shipped in a number of positions and orientations. The terms “die” and “chip” generally refer to the physical object that is the basic workpiece that is transformed by various process operations into the desired integrated circuit device. A die is usually singulated from a wafer, and wafers may be made of semiconducting, non-semiconducting, or combinations of semiconducting and non-semiconducting materials. A board is typically a resin-impregnated fiberglass structure that acts as a mounting substrate for the die.

Reference will now be made to the drawings wherein like structures may be provided with like suffix reference designations. In order to show the structures of various embodiments most clearly, the drawings included herein are diagrammatic representations of integrated circuit structures. Thus, the actual appearance of the fabricated structures, for example in a photomicrograph, may appear different while still incorporating the essential structures of the illustrated embodiments. Moreover, the drawings show the structures necessary to understand the illustrated embodiments. Additional structures known in the art have not been included to maintain the clarity of the drawings.

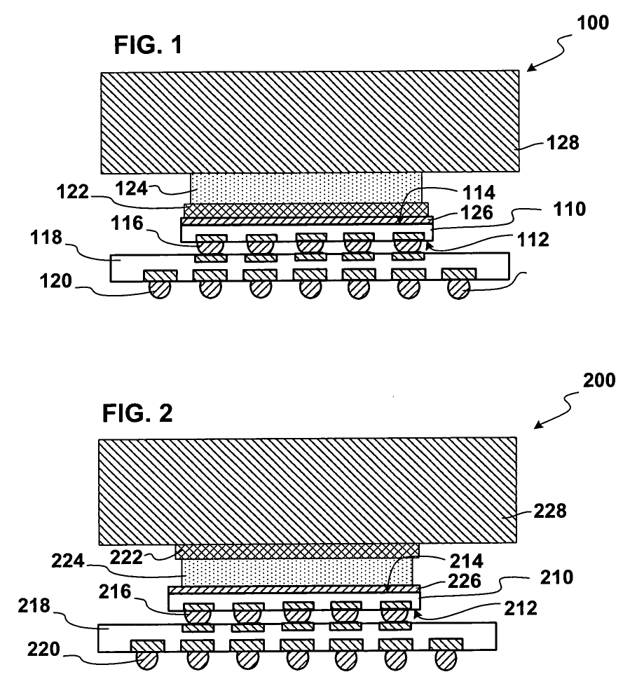

FIG. 1 is a cross-section elevation of an apparatus 100 that includes a dielectric sheet according to an embodiment. The apparatus 100 includes a die 110 with an active surface 112 and a backside surface 114. The die 110 can be electrically bumped by a plurality of solder bumps, one of which is designated with the reference numeral 116. The die 110 is disposed upon a mounting substrate 118 that can be a board such as a printed wiring board, an interposer, a mezzanine board, an expansion card, a motherboard, or other mounting substrates. Electrical communication between the die 110 and the outside world can be achieved by a plurality of mounting substrate bumps, one of which is designated with the reference numeral 120 according to an embodiment.

The thermal solution for conductively cooling the die 110 includes extracting heat through the backside surface 114 of the die 110. In an embodiment, the die 110 is thermally coupled to a dielectric sheet 122. The dielectric sheet 122 is in turn coupled to a thermal interface material (TIM) 124 that is a significant conductor of heat. In an embodiment, the TIM 124 is a metal with a high thermal conductivity in a range that is typical of metals such as copper, aluminum, silver, tin, tin-silver, tin-indium-silver, and the like. In an embodiment, the TIM 124 is a polymer-metal hybrid, which is often referred to as a polymer-solder hybrid (PSH). In an embodiment, the TIM 124 is a metal-metal hybrid, which includes a plurality of first metal particles of a first heat conductivity which are disposed in a matrix of a second metal of a second heat conductivity. In an embodiment, the first heat conductivity is higher than the second heat conductivity. In an embodiment, the second heat conductivity is higher than the first heat conductivity.

In an embodiment, the die 110 includes a backside metallurgy 126 (BSM) that can be applied during the wafer phase of processing. In an embodiment, the dielectric sheet 122 can also be applied during the wafer phase of processing, followed by dicing to achieve the die 110. The BSM 126 can assist the dielectric sheet 122 in adhering to the die 110. For example in FIG. 1, the die 110 and the dielectric sheet 122 are depicted as including the interposed BSM 126 bonded to the die 110 and to the dielectric sheet 122 as a unit. In an embodiment, the BSM 126 is a titanium compound such as sputtered titanium metal. In an embodiment, the BSM 126 includes a titanium first layer disposed against the bare die 110 at the backside surface 114, and a multiphasic, lead-free solder second layer disposed on the first layer. In an embodiment, the lead-free solder second layer is a material with a bulk solder phase such as AgSn, CuSn, AgCu, AgCuSn, and the like.

In addition to the lead-free solder bulk phase, the lead-free solder second layer of the BSM 126 includes an intermetallic second phase that liquefies and dissolves into the first phase during die-attach processing. The intermetallic second phase of the BSM 126 includes an InBiZn as an additive to the first phase. The intermetallic second phase of the BSM 126 causes enhanced wetting upon the titanium first layer at a temperature range from about 95° C. to about 110° C. In this embodiment, the lead-free solder second layer of the BSM 126 is an AgSn solder first phase that includes about 80% to about 95% of the solder, and the intermetallic-forming second phase of the BSM 126 is a zinc-gold-indium intermetallic compound that includes the balance of the solder by weight, about 5% to about 20%. In this embodiment, the zinc-gold-indium intermetallic compound is present with about three parts zinc, five parts Au, and about one part indium.

The die 110, the BSM 126, the dielectric sheet 122, and the TIM 124 are thermally coupled to a heat sink 128. Accordingly, any potentially electrically conductive path between the die 110 and the heat sink 128 is obstructed by the dielectric sheet 122. By the combination of the TIM 124 and the dielectric sheet 122, where the TIM 124 can perform with a heat-transfer capability of unity, i.e., in dimensionless units, but otherwise in units such as Watts/m², the dielectric sheet 122 decreases the heat-transfer capability of the TIM 124 by not more than about 10% of unity according to an embodiment. In an embodiment, the dielectric sheet 122 decreases the heat-transfer capability of the TIM 124 by not more than about 5% of unity. In an embodiment, the dielectric sheet 122 decreases the heat-transfer capability of the TIM 124 by not more than about 1% of unity. In an embodiment, the dielectric sheet 122 decreases the heat-transfer capability of the TIM 124 by not more than about 0.5% of unity. In an embodiment, the dielectric sheet 122 has a thickness of about 50 micrometers (μm). In an embodiment, the dielectric sheet 122 has a thickness of about 20 μm. In an embodiment, the dielectric sheet 122 has a thickness of about 10 μm. In an embodiment, the dielectric sheet 122 has a thickness of about 5 μm. In an embodiment, the dielectric sheet 122 has a thickness that is about 10 percent the thickness of the TIM 124. In an embodiment, the dielectric sheet 122 has a thickness that is about five percent the thickness of the TIM 124. In an embodiment, the dielectric sheet 122 has a thickness that is about one percent the thickness of the TIM 124. In an embodiment, the dielectric sheet 122 has a thickness that is about 0.5 percent the thickness of the TIM 124.

Dielectric Sheet Materials

In an embodiment, the dielectric sheet 122 is an inorganic. In an embodiment, the dielectric sheet 122 is an oxide such as BeO, TiO₂, Al₂O₃, and SiO₂. Other oxide embodiments can be used such as thoria, ceria, and the like. Another oxide embodiment includes spin-on glass (SOG), including silica, borosilicate glass (BSG), phosphosilicate glass (PSB), borophosphosilicate glass (BPSG) and the like. A specific oxide may be chosen for qualities such as dielectric constant, thermal conductivity, adhesion tendency to the die 110, and others. In an embodiment, the dielectric sheet 122 is a nitride such as BN, AlN, and TiN. Other nitride embodiments can be used such as silicon nitride, e.g., amorphous SiₓN_{y}H_{z}, AlBN or the like. In an embodiment, the dielectric sheet 122 is a thin diamond film that can be manufactured by chemical vapor deposition (CVD) during the wafer stage of processing. In an embodiment, the thin diamond film 122 is doped to alter the thermal conductivity and resistivity properties. For the above embodiments, the dielectric sheet 122 can be manufactured by CVD or spin-on processing according to known technique. And these dielectrics constitute selected but non-limiting rigid dielectric sheet embodiments.

In an embodiment, the dielectric sheet 122 is an oxynitride such as boron oxynitride, aluminum oxynitride, silicon oxynitride, and titanium oxynitride. Other oxynitrides can be used according to a specific application.

Various inorganics can be provided as the dielectric sheet 122 by CVD or otherwise. The table enumerates selected inorganics and selected properties.

| | Kc 100° C., | Kc 1400° C., | Resistivity, |
|---|---|---|---|
| Compound | cal/cm-sec-K | cal/cm-sec-K | 293 K, Ω-cm |
| Y₂O₃ | 0.034 | 0.007 | 10⁸ |
| ZrO₂ | 0.005 | 0.006 | 10¹-10⁸ |
| Al₂O₃ | 0.072 | 0.013 | 10¹⁶ |
| BN | ˜0.075 | ˜0.05 | 10¹³ |
| TiN | 0.069 | ˜0.018 | 22 × 10⁴ |
| SiN | ˜0.06 | — | — |
| PVD diamond | ˜3.6 | — | 10¹⁶ |

In an embodiment, the dielectric sheet 122 is an organic film such as a high-k dielectric, e.g., a non-conductive polymer with a dielectric constant greater than or equal to about 4. Such non-conductive polymers are conventional before applying them to an IC package embodiment as set forth in this disclosure. And these organic dielectrics constitute selected but non-limiting flexible dielectric sheet embodiments.

In an embodiment, the dielectric sheet 122 includes a combination of at least two of any disclosed oxide, nitride, SOG oxide, oxynitride, thin diamond film, and organic.

FIG. 2 is a cross-section elevation of an apparatus 200 that includes a dielectric sheet according to an embodiment. The apparatus 200 includes a die 210 with an active surface 212 and a backside surface 214. The die 210 can be electrically bumped by a plurality of solder bumps, one of which is designated with the reference numeral 216. The die 210 is disposed upon a mounting substrate 218 that can be a board such as a printed wiring board, an interposer, a mezzanine board, an expansion card, a motherboard, or other mounting substrates. Electrical communication between the die 210 and the outside world can be achieved by a plurality of mounting substrate bumps, one of which is designated with the reference numeral 220 according to a embodiment.

The thermal solution for conductively cooling the die 210 includes extracting heat through the backside surface 214 of the die 210. In an embodiment, the die 210 is thermally coupled to a TIM 224 that is a significant conductor of heat. The TIM 224 is in turn coupled to a dielectric sheet 222. In an embodiment, the TIM 224 is a metal with a high thermal conductivity in a range that is typical of metals such as copper, aluminum, silver, tin, tin-silver, tin-indium-silver, and the like. In an embodiment, the TIM 224 is a polymer-metal hybrid, such as PSH. In an embodiment, the TIM 224 is a metal-metal hybrid, which includes a plurality of first metal particles of a first heat conductivity which are disposed in a matrix of a second metal of a second heat conductivity. In an embodiment, the first heat conductivity is higher than the second heat conductivity. In an embodiment, the second heat conductivity is higher than the first heat conductivity.

In an embodiment, the die 210 includes a BSM 226 that can be applied during the wafer phase of processing. The BSM 226 can assist the TIM 224 in adhering to the die 210. For example in FIG. 2, the die 210 and the TIM 224 are depicted as including the BSM 226 bonded to the die 210 and to the TIM 224 as a unit. Any embodiment of a BSM set forth in this disclosure can be used between the die 210 and the TIM 224.

The die 210, the BSM 226, and the TIM 224 are thermally coupled to a heat sink 228 through a dielectric sheet 222. Accordingly, any potentially electrically conductive path between the die 210 and the heat sink 228 is obstructed by the dielectric sheet 222. By the combination of the TIM 224 and the dielectric sheet 222, where the TIM 224 can perform with a heat-transfer capability of unity, i.e., in dimensionless units, but otherwise in units such as Watts/m², the dielectric sheet 222 decreases the heat-transfer capability of the TIM 224 by not more than about 10% of unity according to an embodiment. In an embodiment, the dielectric sheet 222 decreases the heat-transfer capability of the TIM 224 by not more than about 5% of unity. In an embodiment, the dielectric sheet 222 decreases the heat-transfer capability of the TIM 224 by not more than about 1% of unity. In an embodiment, the dielectric sheet 222 decreases the heat-transfer capability of the TIM 224 by not more than about 0.5% of unity. In an embodiment, the dielectric sheet 222 has a thickness of about 50 micrometers (μm). In an embodiment, the dielectric sheet 222 has a thickness of about 20 μm. In an embodiment, the dielectric sheet 222 has a thickness of about 10 μm. In an embodiment, the dielectric sheet 222 has a thickness of about 5 μm. In an embodiment, the dielectric sheet 222 has a thickness that is about 10 percent the thickness of the TIM 224. In an embodiment, the dielectric sheet 222 has a thickness that is about five percent the thickness of the TIM 224. In an embodiment, the dielectric sheet 222 has a thickness that is about one percent the thickness of the TIM 224. In an embodiment, the dielectric sheet 222 has a thickness that is about 0.5 percent the thickness of the TIM 224.

In an embodiment, the dielectric sheet 222 includes a combination of at least two of any disclosed oxide, nitride, SOG oxide, oxynitride, thin diamond film, and organic.

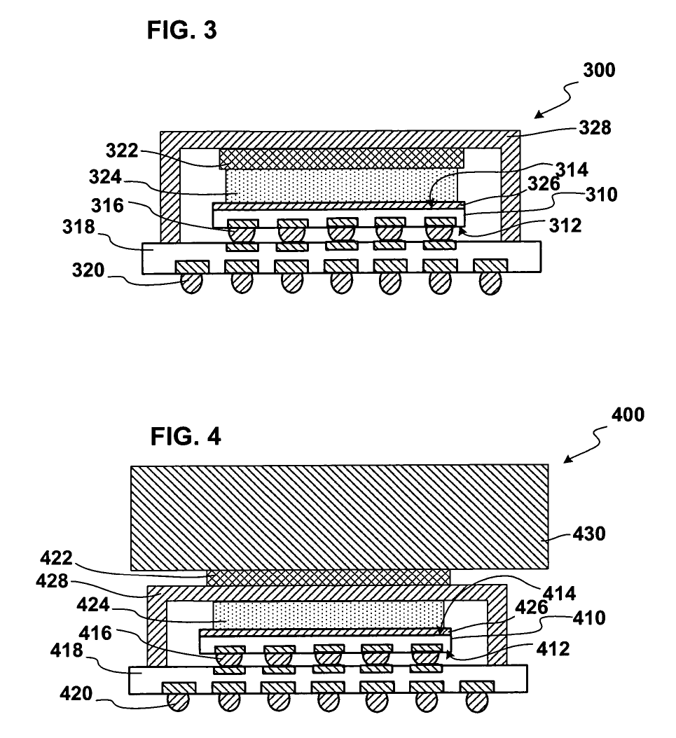

FIG. 3 is a cross-section elevation of an apparatus 300 that includes a dielectric sheet in an integrated heat spreader package according to an embodiment. The apparatus 300 includes a die 310 with an active surface 312 and a backside surface 314. The die 310 can be electrically bumped by a plurality of solder bumps, one of which is designated with the reference numeral 316. The die 310 is disposed upon a mounting substrate 318 that can be a board such as a printed wiring board, an interposer, a mezzanine board, an expansion card, a motherboard, or other mounting substrates. Electrical communication between the die 310 and the outside world can be achieved by a plurality of mounting substrate bumps, one of which is designated with the reference numeral 320 according to a embodiment.

The thermal solution for conductively cooling the die 310 includes extracting heat through the backside surface 314 of the die 310. In an embodiment, the die 310 is thermally coupled to a TIM 324 that is a significant conductor of heat. The TIM 324 is in turn coupled to a dielectric sheet 322. In an embodiment, the TIM 324 is a metal with a high thermal conductivity in a range that is typical of metals such as copper, aluminum, silver, tin, tin-silver, tin-indium-silver, and the like. In an embodiment, the TIM 324 is a polymer-metal hybrid, such as PSH. In an embodiment, the TIM 324 is a metal-metal hybrid, which includes a plurality of first metal particles of a first heat conductivity which are disposed in a matrix of a second metal of a second heat conductivity. In an embodiment, the first heat conductivity is higher than the second heat conductivity. In an embodiment, the second heat conductivity is higher than the first heat conductivity.

In an embodiment, the die 310 includes a BSM 326 that can be applied during the wafer phase of processing. The BSM 326 can assist the TIM 324 in adhering to the die 310. For example in FIG. 3, the die 310 and the TIM 324 are depicted as including the BSM 326 bonded to the die 310 and to the TIM 324 as a unit. Any embodiment of a BSM set forth in this disclosure can be used between the die 310 and the TIM 324.

The die 310, the BSM 326, and the TIM 324 are thermally coupled to an integrated heat spreader (IHS) 328 through a dielectric sheet 322. Accordingly, any potentially electrically conductive path between the die 310 and the IHS 328 is obstructed by the dielectric sheet 322. By the combination of the TIM 224 and the dielectric sheet 322, where the TIM 324 can perform with a heat-transfer capability of unity, i.e., in dimensionless units, but otherwise in units such as Watts/m², the dielectric sheet 322 decreases the heat-transfer capability of the TIM 324 by not more than about 10% of unity according to an embodiment. In an embodiment, the dielectric sheet 322 decreases the heat-transfer capability of the TIM 324 by not more than about 5% of unity. In an embodiment, the dielectric sheet 322 decreases the heat-transfer capability of the TIM 324 by not more than about 1% of unity. In an embodiment, the dielectric sheet 322 decreases the heat-transfer capability of the TIM 324 by not more than about 0.5% of unity. In an embodiment, the dielectric sheet 322 has a thickness of about 50 micrometers (μm). In an embodiment, the dielectric sheet 322 has a thickness of about 20 μm. In an embodiment, the dielectric sheet 322 has a thickness of about 10 μm. In an embodiment, the dielectric sheet 322 has a thickness of about 5 μm. In an embodiment, the dielectric sheet 322 has a thickness that is about 10 percent the thickness of the TIM 324. In an embodiment, the dielectric sheet 322 has a thickness that is about five percent the thickness of the TIM 324. In an embodiment, the dielectric sheet 322 has a thickness that is about one percent the thickness of the TIM 324. In an embodiment, the dielectric sheet 322 has a thickness that is about 0.5 percent the thickness of the TIM 324.

In an embodiment, the dielectric sheet 322 includes a combination of at least two of any disclosed oxide, nitride, SOG oxide, oxynitride, thin diamond film, and organic.

FIG. 4 is a cross-section elevation of an apparatus 400 that includes a dielectric sheet in an integrated heat spreader and heat slug package according to an embodiment. The apparatus 400 includes a die 410 with an active surface 412 and a backside surface 414. The die 410 can be electrically bumped by a plurality of solder bumps, one of which is designated with the reference numeral 416. The die 410 is disposed upon a mounting substrate 418 that can be a board such as a printed wiring board, an interposer, a mezzanine board, an expansion card, a motherboard, or other mounting substrates. Electrical communication between the die 410 and the outside world can be achieved by a plurality of mounting substrate bumps, one of which is designated with the reference numeral 420 according to a embodiment.

The thermal solution for conductively cooling the die 410 includes extracting heat through the backside surface 414 of the die 410. In an embodiment, the die 410 is thermally coupled to a TIM 424 that is a significant conductor of heat. The TIM 424 is in turn coupled to an IHS 428. The IHS 428 is in turn coupled to a dielectric sheet 422 that is in turn coupled to a heat slug 430. In an embodiment, the TIM 424 is a metal with a high thermal conductivity in a range that is typical of metals such as copper, aluminum, silver, tin, tin-silver, tin-indium-silver, and the like. In an embodiment, the TIM 424 is a polymer-metal hybrid, such as PSH. In an embodiment, the TIM 424 is a metal-metal hybrid, which includes a plurality of first metal particles of a first heat conductivity which are disposed in a matrix of a second metal of a second heat conductivity. In an embodiment, the first heat conductivity is higher than the second heat conductivity. In an embodiment, the second heat conductivity is higher than the first heat conductivity.

In an embodiment, the heat slug 430 is a heat-transfer article such as a heat pipe. In an embodiment, the heat slug 430 is a heat-transfer article such as an air-cooled heat sink. In an embodiment, the heat slug 430 is a heat-transfer article such as a convection air-cooled heat sink.

In an embodiment, the die 410 includes a BSM 426 that can be applied during the wafer phase of processing. The BSM 426 can assist the TIM 424 in adhering to the die 410. For example in FIG. 4, the die 410 and the TIM 424 are depicted as including the BSM 426 bonded to the die 410 and to the TIM 424 as a unit. Any embodiment of a BSM set forth in this disclosure can be used between the die 410 and the TIM 424.

The die 410, the BSM 426, the TIM 424 and the IHS 428 are thermally coupled to the heat slug 430 through a dielectric sheet 422. Accordingly, any potentially electrically conductive path between the die 410 and the heat slug 430 is obstructed by the dielectric sheet 422. By the combination of the TIM 424 and the dielectric sheet 422, where the TIM 424 can perform with a heat-transfer capability to the heat slug 430 of unity, i.e., in dimensionless units, but otherwise in units such as Watts/m², the dielectric sheet 422 decreases the heat-transfer capability of the TIM 424 by not more than about 10% of unity. In an embodiment, the dielectric sheet 422 decreases the heat-transfer capability of the TIM 424 by not more than about 5% of unity. In an embodiment, the dielectric sheet 422 decreases the heat-transfer capability of the TIM 424 by not more than about 1% of unity. In an embodiment, the dielectric sheet 422 decreases the heat-transfer capability of the TIM 424 by not more than about 0.5% of unity. In an embodiment, the dielectric sheet 422 has a thickness of about 50 micrometers (μm). In an embodiment, the dielectric sheet 422 has a thickness of about 20 μm. In an embodiment, the dielectric sheet 422 has a thickness of about 10 μm. In an embodiment, the dielectric sheet 422 has a thickness of about 5 μm. In an embodiment, the dielectric sheet 422 has a thickness that is about 10 percent the thickness of the TIM 424. In an embodiment, the dielectric sheet 422 has a thickness that is about five percent the thickness of the TIM 424. In an embodiment, the dielectric sheet 422 has a thickness that is about one percent the thickness of the TIM 424. In an embodiment, the dielectric sheet 422 has a thickness that is about 0.5 percent the thickness of the TIM 424.

In an embodiment, the dielectric sheet 422 includes a combination of at least two of any disclosed oxide, a nitride, an SOG oxide, oxynitride, thin diamond film, and organic.

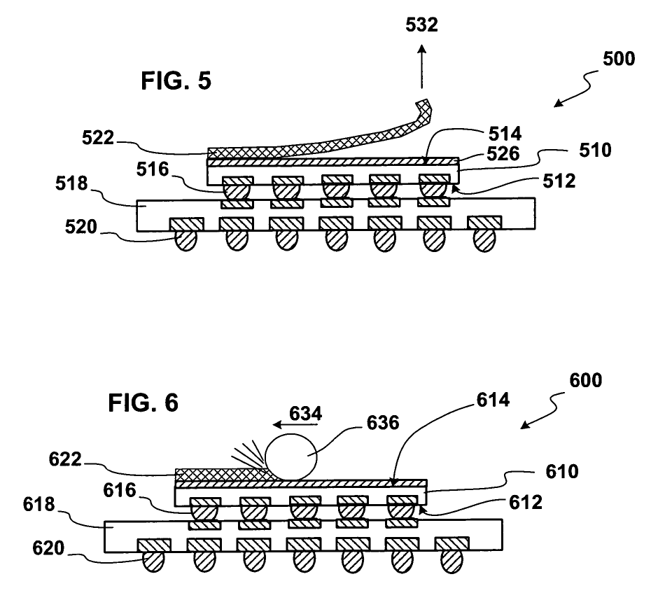

FIG. 5 is a cross-section elevation of an apparatus 500 during the reworking of a flexible dielectric sheet according to an embodiment. The apparatus 500 includes a die 510 with an active surface 512 and a backside surface 514. The die 510 can be electrically bumped by a plurality of solder bumps, one of which is designated with the reference numeral 516. The die 510 is disposed upon a mounting substrate 518 that can be a board such as a printed wiring board, an interposer, a mezzanine board, an expansion card, a motherboard, or other mounting substrates. Electrical communication between the die 510 and the outside world can be achieved by a plurality of mounting substrate bumps, one of which is designated with the reference numeral 520 according to a embodiment.

In an embodiment, reworking of the thermal solution for the die 510 includes removing a dielectric sheet 522 and installing a replacement dielectric sheet. As depicted in FIG. 5, the dielectric sheet 522 is disposed directly upon a BSM 526 of the die 510. Where the dielectric sheet 522 is flexible, it can be peeled off the BSM 526 if present, or it can be peeled off the backside surface 514 of the die 510 if the BSM 526 is not present. The dielectric sheet 522 is being peeled off in the direction of the directional arrow 532.

Reworking the thermal solution according to these embodiments can be achieved during initial processing before shipping, if a different dielectric sheet is desired to replace the dielectric sheet 522. Similarly, reworking the thermal solution according to these embodiments can be achieved after shipping, i.e., if the apparatus 500 requires a different thermal solution than that with which it was shipped.

FIG. 6 is a cross-section elevation of an apparatus 600 during the reworking of a rigid dielectric sheet according to an embodiment. The apparatus 600 includes a die 610 with an active surface 612 and a backside surface 614. The die 610 can be electrically bumped by a plurality of solder bumps, one of which is designated with the reference numeral 616. The die 610 is disposed upon a mounting substrate 618 that can be a board such as a printed wiring board, an interposer, a mezzanine board, an expansion card, a motherboard, or other mounting substrates. Electrical communication between the die 610 and the outside world can be achieved by a plurality of mounting substrate bumps, one of which is designated with the reference numeral 620 according to a embodiment.

In an embodiment, reworking of the thermal solution for the die 610 includes removing a dielectric sheet 622 and installing a replacement dielectric sheet. As depicted in FIG. 6, the dielectric sheet 622 is disposed directly upon a BSM 626 of the die 610. Where the dielectric sheet 622 is rigid such as an oxide, a nitride, a thin diamond film, or others, it can be removed from the BSM 626 by grinding if present, or it can be ground off the backside surface 614 of the die 610 if the BSM 626 is not present. The dielectric sheet 622 is being ground off in the direction of the directional arrow 634, with a grinding wheel 636 according to an embodiment.

Reworking the thermal solution according to these embodiments can be achieved during initial processing if a different dielectric sheet is desired to replace the dielectric sheet 622. Similarly, reworking the thermal solution according to these embodiments can be achieved after shipping, i.e., if the apparatus 600 requires a different thermal solution than that with it was shipped.

In an embodiment, a method of operating an IC device includes applying a bias to a die. Reference is made to FIG. 1. In an embodiment, a bias is applied across a circuit through the solder bumps 116, such that a bias is imposed upon the die 110. In an embodiment, a bias that is a fraction of the voltage requirement of the die 110 is applied across a circuit in the solder bumps 116, such that a bias is imposed upon the die 110. Accordingly, current leakage diminishes. In an embodiment, a bias in a range from about five percent to about 50 percent of the voltage requirement of the die 110 is applied across a circuit in the die 110 through the solder bumps 116, such that a bias is imposed upon the die 110. Accordingly, current leakage diminishes. In an embodiment, the voltage that is applied is a range from about 1 Volt to about 6 Volts. In an embodiment, a bias of about five percent of the voltage requirement of the die 110, about 3.5 Volts, is applied across a circuit in the die 110 through the solder bumps 116, such that a bias is imposed upon the entire integrated circuitry of the die 110. Accordingly, current leakage diminishes.

In an embodiment, the IC device that includes a dielectric sheet embodiment is a mobile device such as the apparatus 100 depicted in FIG. 1. In an embodiment, the IC device is a desktop device such as the apparatus 300 depicted in FIG. 3. In an embodiment, the IC device is a desktop device such as the apparatus 400 depicted in FIG. 4. In FIG. 4, although some current leakage may occur through the IHS 428, because of the dielectric sheet 422, significant current leakage is prevented to the larger heat sink that is the heat slug 430.

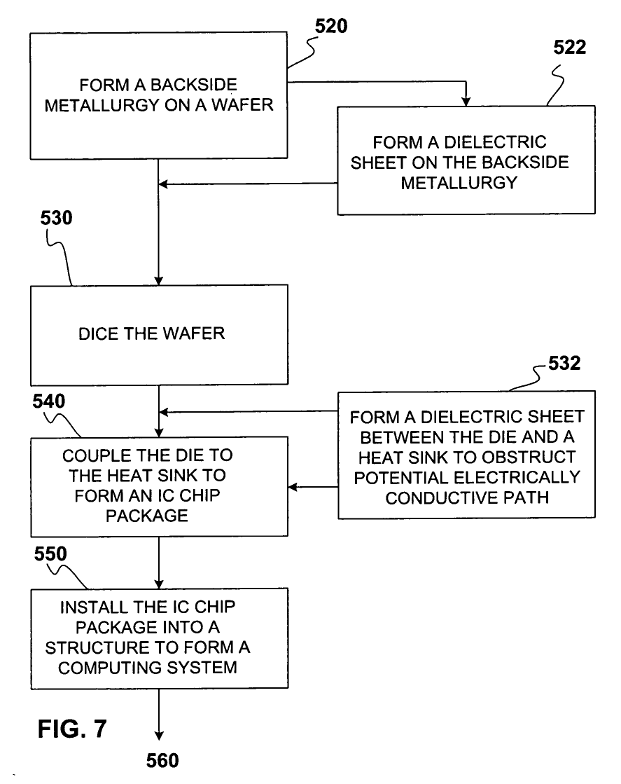

FIG. 7 is a flow chart that describes process flow embodiments 700.

At 710 the process includes forming a BSM upon a wafer before singulating the wafer into dice. In an embodiment, the BSM is any BSM example set forth in this disclosure. At 712 the process includes forming a dielectric sheet on the BSM of the wafer. In an embodiment at 712 the process includes forming a dielectric sheet on the backside surface of the wafer if no BSM is present.

At 720, the process includes dicing the wafer. In an embodiment, the process includes 712 and concludes at 720.

At 730, the process includes forming a dielectric sheet between a die and a heat sink to obstruct any potentially electrically conductive path therebetween. In an embodiment, the process includes 710, 720, and concludes at 730.

At 740, the process includes coupling the die to the heat sink, with the dielectric sheet therebetween, to form an IC chip package. In an embodiment, the process includes reflow heating of the BSM during coupling of the die to the heat sink as set forth in this disclosure. In an embodiment, the process commences and terminates at 740. In an embodiment, the process commences at 730 and terminates at 740.

At 750, the process includes removing the dielectric sheet and installing a replacement dielectric sheet.

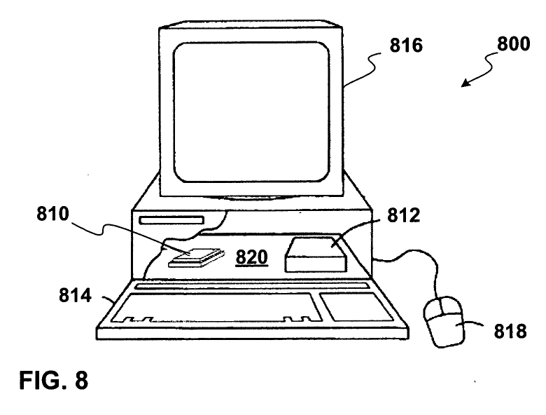

At 760, the process includes installing the IC chip package to a structure to form a computing system. According to an embodiment illustrated in FIG. 8, the structure can be a computer shell or a board 820. In an embodiment, the process commences at 760 and terminates at 770.

FIG. 8 is a cut-away elevation that depicts a computing system 800 according to an embodiment. One or more of the foregoing embodiments of the dielectric sheet embodiments may be utilized in a computing system, such as a computing system 800 of FIG. 8. Hereinafter any dielectric sheet embodiment alone or in combination with any other embodiment is referred to as an embodiment(s) configuration.

The computing system 800 includes at least one processor (not pictured), which is enclosed in an IC chip package 810, a data storage system 812, at least one input device such as a keyboard 814, and at least one output device such as a monitor 816, for example. The computing system 800 includes a processor that processes data signals, and may include, for example, a microprocessor, available from Intel Corporation. In addition to the keyboard 814, the computing system 800 can include another user input device such as a mouse 818, for example. The computing system 800 can include a structure, after processing as depicted in FIG. 3, including the die 310, the dielectric sheet 322, and the integrated heat spreader 328.

For purposes of this disclosure, a computing system 800 embodying components in accordance with the claimed subject matter may include any system that utilizes a microelectronic device system, which may include, for example, at least one of the dielectric sheet embodiments that is coupled to data storage such as dynamic random access memory (DRAM), polymer memory, flash memory, and phase-change memory. In this embodiment, the embodiment(s) is coupled to any combination of these functionalities by being coupled to a processor. In an embodiment, however, an embodiment(s) configuration set forth in this disclosure is coupled to any of these functionalities. For an example embodiment, data storage includes an embedded DRAM cache on a die. Additionally in an embodiment, the embodiment(s) configuration that is coupled to the processor (not pictured) is part of the system with an embodiment(s) configuration that is coupled to the data storage of the DRAM cache. Additionally in an embodiment, an embodiment(s) configuration is coupled to the data storage 812.

In an embodiment, the computing system 800 can also include a die that contains a digital signal processor (DSP), a micro controller, an application specific integrated circuit (ASIC), or a microprocessor. In this embodiment, the embodiment(s) configuration is coupled to any combination of these functionalities by being coupled to a processor. For an example embodiment, a DSP is part of a chipset that may include a stand-alone processor and the DSP as separate parts of the chipset on the board 820. In this embodiment, an embodiment(s) configuration is coupled to the DSP, and a separate embodiment(s) configuration may be present that is coupled to the processor in the IC chip package 810. Additionally in an embodiment, an embodiment(s) configuration is coupled to a DSP that is mounted on the same board 820 as the IC chip package 810. It can now be appreciated that the embodiment(s) configuration can be combined as set forth with respect to the computing system 800, in combination with an embodiment(s) configuration as set forth by the various embodiments of the dielectric sheet within this disclosure and their equivalents.

It can now be appreciated that embodiments set forth in this disclosure can be applied to devices and apparatuses other than a traditional computer. For example, a die can be packaged with an embodiment(s) configuration, and placed in a portable device such as a wireless communicator or a hand-held device such as a personal data assistant and the like. Another example is a die that can be packaged with an embodiment(s) configuration and placed in a vehicle such as an automobile, a locomotive, a watercraft, an aircraft, or a spacecraft.

The Abstract is provided to comply with 37 C.F.R. §1.72(b) requiring an abstract that will allow the reader to quickly ascertain the nature and gist of the technical disclosure. It is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate preferred embodiment.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

1. (canceled)

2. The apparatus of claim 3, wherein the dielectric sheet is selected from:
a diamond film;
an oxide sheet selected from BeO, TiO2, Al2O3, SiO2, and spin-on glass;
a nitride sheet selected from AlN, SiN, BN, and TiN;
an organic sheet; and
a composite sheet selected from a diamond film, an oxide sheet, a nitride sheet, an organic sheet, and combinations thereof.

3. An apparatus comprising:
a die including an active surface and a backside surface;
a thermal interface material disposed above the die backside surface;
a heat sink disposed above the thermal interface material; and
a dielectric sheet adapted and disposed to obstruct any potentially electrically conductive path between the die and the heat sink, wherein the dielectric sheet is disposed above and on the die, and below and on the thermal interface material.

4. An apparatus comprising:
a die including an active surface and a backside surface;
a thermal interface material disposed above the die backside surface;
a heat sink disposed above the thermal interface material; and
a dielectric sheet adapted and disposed to obstruct any potentially electrically conductive path between the die and the heat sink, wherein the thermal interface material is disposed above and on the die, and below and on the dielectric sheet.

5. An apparatus comprising:
a die including an active surface and a backside surface;
a thermal interface material disposed above the die backside surface;
a heat sink disposed above the thermal interface material; and a dielectric sheet adapted and disposed to obstruct any potentially electrically conductive path between the die and the heat sink, wherein the thermal interface material is disposed above and on the die, and below and on the dielectric sheet, and the heat sink is an integrated heat spreader disposed above and on the dielectric sheet.

6. An apparatus comprising:
a die including an active surface and a backside surface;
a thermal interface material disposed above the die backside surface;
a heat sink disposed above the thermal interface material; and
a dielectric sheet adapted and disposed to obstruct any potentially electrically conductive path between the die and the heat sink, wherein the thermal interface material is disposed above and on the die, and below and on the heat sink;
the dielectric sheet is disposed above and on the heat sink; and
the heat sink is an integrated heat spreader, and the apparatus further including a heat slug disposed above and on the dielectric sheet.

7. The apparatus of claim 3, wherein the thermal interface material has a heat-transfer capability of unity, and wherein the dielectric sheet decreases the heat-transfer capability the thermal interface material to not less than 10 percent of unity.

8. The apparatus of claim 3, wherein at least one of the thermal interface material and the dielectric sheet is reworkable.

9. The apparatus of claim 3, further including a backside metallurgy disposed on the backside surface.

10. The apparatus of claim 3, wherein the dielectric sheet is not more than about 10 percent the thickness of the thermal interface material.

11-24. (canceled)

25. The apparatus of claim 4, wherein the dielectric sheet is selected from:
a diamond film;
an oxide sheet selected from BeO, TiO2, Al2O3, SiO2, and spin-on glass;
a nitride sheet selected from AlN, SiN, BN, and TiN;
an organic sheet; and
a composite sheet selected from a diamond film, an oxide sheet, a nitride sheet, an organic sheet, and combinations thereof.

26. The apparatus of claim 4, wherein the thermal interface material has a heat-transfer capability of unity, and wherein the dielectric sheet decreases the heat-transfer capability the thermal interface material to not less than 10 percent of unity.

27. The apparatus of claim 4, wherein at least one of the thermal interface material and the dielectric sheet is reworkable.

28. The apparatus of claim 4, further including a backside metallurgy disposed on the backside surface.

29. The apparatus of claim 4, wherein the dielectric sheet is not more than about 10 percent the thickness of the thermal interface material.

30. The apparatus of claim 5, wherein the dielectric sheet is selected from:
a diamond film;
an oxide sheet selected from BeO, TiO2, Al2O3, SiO2, and spin-on glass;
a nitride sheet selected from AlN, SiN, BN, and TiN;
an organic sheet; and
a composite sheet selected from a diamond film, an oxide sheet, a nitride sheet, an organic sheet, and combinations thereof.

31. The apparatus of claim 5, wherein the thermal interface material has a heat-transfer capability of unity, and wherein the dielectric sheet decreases the heat-transfer capability the thermal interface material to not less than 10 percent of unity.

32. The apparatus of claim 5, wherein at least one of the thermal interface material and the dielectric sheet is reworkable.

33. The apparatus of claim 5, further including a backside metallurgy disposed on the backside surface.

34. The apparatus of claim 5, wherein the dielectric sheet is not more than about 10 percent the thickness of the thermal interface material.

35. The apparatus of claim 6, wherein the dielectric sheet is selected from:
a diamond film;
an oxide sheet selected from BeO, TiO2, Al2O3, SiO2, and spin-on glass;
a nitride sheet selected from AlN, SiN, BN, and TiN;
an organic sheet; and
a composite sheet selected from a diamond film, an oxide sheet, a nitride sheet, an organic sheet, and combinations thereof.

36. The apparatus of claim 6, wherein the thermal interface material has a heat-transfer capability of unity, and wherein the dielectric sheet decreases the heat-transfer capability the thermal interface material to not less than 10 percent of unity.

37. The apparatus of claim 6, wherein at least one of the thermal interface material and the dielectric sheet is reworkable.

38. The apparatus of claim 6, further including a backside metallurgy disposed on the backside surface.

39. The apparatus of claim 6, wherein the dielectric sheet is not more than about 10 percent the thickness of the thermal interface material.
